(19) United States
(12) Patent Application Publication
(10) Pub. No.: US 2025/0120014 A1
(43) Pub. Date: Apr. 10, 2025

(54) CIRCUIT BOARD AND METHOD OF FABRICATING CIRCUIT BOARD

(71) Applicant: SAMSUNG ELECTRO-MECHANICS CO., LTD., Suwon-si (KR)

(72) Inventor: Youngwoong Cho, Suwon-si (KR)

(73) Assignee: SAMSUNG ELECTRO-MECHANICS CO., LTD., Suwon-si (KR)

(21) Appl. No.: 18/680,375

(22) Filed: May 31, 2024

(30) Foreign Application Priority Data
Oct. 4, 2023 (KR) 10-2023-0131800

(51) Int. Cl. H05K 1/02; H05K 1/11; H05K 3/42

(52) U.S. Cl. CPC H05K 1/0298; H05K 1/0271; H05K 1/115; H05K 3/425

(57) ABSTRACT

A circuit board including a substrate having a first surface and a second surface facing each other, including an insulating layer disposed between the first surface and the second surface, and having a cavity penetrating in a direction perpendicular to the first surface, a first wiring pattern embedded in the insulating layer on the first surface to enable signal transmission, and a first reinforcement pattern embedded in the insulating layer on the first surface, disposed around the cavity to be spaced apart from an edge of the cavity, and configured to be separated from the first wiring pattern.

### CROSS-REFERENCE TO RELATED APPLICATION

This application claims priority to and the benefit of Korean Patent Application No. 10-2023-0131800 filed in the Korean Intellectual Property Office on Oct. 4, 2023, the entire contents of which are incorporated herein by reference.

### BACKGROUND

### (a) Technical Field

The present disclosure relates to a circuit board and a method of fabricating a circuit board.

### (b) Description of the Related Art

Due to the trend of miniaturization and multifunctionality of electronic products, semiconductor packaging technology is becoming highly integrated and high-performance. Existing interposer POP packaging technology had limitations in heat dissipation effects due to restrictions on the thickness of the mounted chip. Accordingly, panel level package (PLP) packaging technology, which relaxes chip thickness restrictions and improves heat dissipation effects, is attracting attention.

PLP packaging uses prepreg (PPG) type printed circuit boards. PPG is made up of resin and glass fabric stacked together.

If a smear removal process is performed after cavity processing, the glass fibers are etched, which may cause cracks in the PPG resin area due to mechanical/physical loads during the packaging process.

These cracks can cause application defects when applying photo-imageable dielectric material in the PLP packaging process. Therefore, it has become necessary to improve the structure of the circuit board and a method of fabricating the circuit board, ensuring the quality of the cavity area of the printed circuit board, which is the chip mounting area.

### SUMMARY

One aspect of the embodiment attempts to provide a circuit board and a method of fabricating the circuit board capable of suppressing cracks in the resin area at the edge of the cavity of the printed circuit board.

However, embodiments of the present disclosure are not limited to those mentioned above, and may be variously extended in the scope of the technical ideas included in the present disclosure.

A circuit board according to an embodiment includes: a substrate having a first surface and a second surface facing each other, including an insulating layer disposed between the first surface and the second surface, and having a cavity penetrating in a direction perpendicular to the first surface; a first wiring pattern embedded in the insulating layer on the first surface to enable signal transmission; and a first reinforcement pattern embedded in the insulating layer on the first surface, disposed around the cavity to be spaced apart from an edge of the cavity, and separated from the first wiring pattern.

The first reinforcement pattern may include metal.

The first reinforcement pattern may be electrically isolated.

The first reinforcement pattern may be covered with the insulating layer so as to be not exposed to the cavity.

The first reinforcement pattern may have the same height as the first wiring pattern.

The first wiring pattern may be spaced apart from the first reinforcement pattern in a direction away from the cavity.

The circuit board may include: a second wiring pattern disposed on the insulating layer on the second surface to enable signal transmission; a second reinforcement pattern disposed on the insulating layer on the second surface around the cavity, spaced apart from the edge of the cavity, and separated from the second wiring pattern; and a via embedded in the insulating layer and connecting the first wiring pattern and the second wiring pattern to each other.

The second reinforcement pattern may protrude above the second surface to have the same height as the second wiring pattern.

The second wiring pattern may be spaced apart from the second reinforcement pattern in a direction away from the cavity.

The first reinforcement pattern and the second reinforcement pattern may be disposed so that at least a part of the first reinforcement pattern and the second reinforcement pattern overlap each other along a direction perpendicular to the first surface.

The first reinforcement pattern may include a plurality of reinforcement pads spaced apart from each other along the edge of the cavity.

The first reinforcement pattern may be configured to continuously connected along the edge of the cavity and surround the cavity.

The cavity may include four sides, and the first reinforcement pattern may include reinforcement pads disposed on each of the four sides.

The first reinforcement pattern may extend from the first surface and into the insulating layer.

A central axis of the first reinforcement pattern along a thickness direction of the circuit board may be offset from a central axis of the second reinforcement pattern along the thickness direction of the circuit board.

An electronic device package according to another embodiment includes: a substrate having a first surface and a second surface facing each other, including an insulating layer disposed between the first surface and the second surface, and having a cavity penetrating in a direction perpendicular to the first surface; a first wiring pattern embedded in the insulating layer on the first surface to enable signal transmission; a first reinforcement pattern embedded in the insulating layer on the first surface, disposed around the cavity to be spaced apart from an edge of the cavity, and from the first wiring pattern; a redistribution layer disposed on the first surface of the substrate; and an electronic device accommodated in the cavity and connected to the redistribution layer.

The electronic device may further include an insulating protective layer disposed between the first surface of the substrate and the redistribution layer to cover the first reinforcement pattern.

The first reinforcement pattern may be electrically isolated.

The first reinforcement pattern may be covered with the insulating layer so as to be not exposed to the cavity.

The first wiring pattern may be spaced apart from the first reinforcement pattern in a direction away from the cavity.

According to the circuit board according to the embodiment, it is possible to secure packaging yield by suppressing the occurrence of cracks in the resin area at the edge of the cavity during the panel level package (PLP) process. Additionally, it is possible to improve coating defects when applying photo-imageable dielectric (PID) material in the PLP process.

### BRIEF DESCRIPTION OF THE DRAWINGS

FIG. 1 is a cross-sectional view illustrating an electronic device package showing an electronic device mounted on a circuit board according to an embodiment.

FIGS. 2 to 14 are cross-sectional process views illustrating a method of fabricating a circuit board according to an embodiment.

FIG. 15 is a bottom view of a circuit board according to an embodiment.

FIGS. 16 to 18 are plan views of circuit boards according to other embodiments.

### DETAILED DESCRIPTION

Hereinafter, the present disclosure will be described in detail hereinafter with reference to the accompanying drawings, in which embodiments of the present disclosure are shown. The drawings and description are to be regarded as illustrative in nature and not restrictive. Like reference numerals designate like elements throughout the specification. In the accompanying drawings, some constituent elements are exaggerated, omitted, or schematically illustrated, and the size of each constituent element does not entirely reflect the actual size.

The accompanying drawings are intended only to facilitate an understanding of the exemplary embodiments disclosed in this specification, and it is to be understood that the technical ideas disclosed herein are not limited by the accompanying drawings and include all modifications, equivalents, or substitutions that are within the range of the ideas and technology of the present disclosure.

Although terms of “first,” “second,” and the like are used to explain various constituent elements, the constituent elements are not limited to such terms. These terms are only used to distinguish one constituent element from another constituent element.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

Throughout the specification, the terms “comprise” or “have” are intended to specify the presence of stated features, integers, steps, operations, constituent elements, components or a combination thereof, but do not preclude the presence or addition of one or more other features, integers, steps, operations, constituent elements, components, and/or groups thereof. Therefore, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Throughout the specification, the term “connected” does not mean only that two or more constituent components are directly connected, but may also mean that two or more constituent components are indirectly connected through another constituent component, that two or more components are electrically connected as well as physically connected, or that two or more constituent components are referred to by different names but are united by location or function.

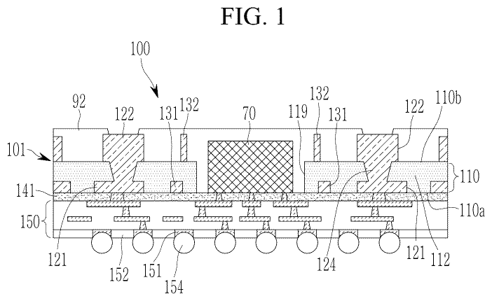

FIG. 1 is a cross-sectional view illustrating an electronic device package showing an electronic device mounted on a circuit board according to an embodiment.

Referring to FIG. 1, an electronic device package 100 may be configured by mounting an electronic device 70 on a circuit board 101 according to the embodiment. The electronic device 70 may include various devices such as active elements, passive elements, and integrated circuits (ICs), and may be, for example, a semiconductor chip. The circuit board 101 may be used for a semiconductor package and may be configured as a printed circuit board.

The circuit board 101 includes a substrate 110 having a first surface 110a and a second surface 110b facing each other and including an insulating layer 112, and wiring patterns 121 and 122 disposed inside or on the surface of the substrate 110. The substrate 110 has a cavity 119 penetrating in a direction perpendicular to the first surface 110a. Reinforcement patterns 131 and 132 may be disposed inside or on the surface of the insulating layer 112 around the cavity 119.

The wiring patterns 121 and 122 may include the first wiring pattern 121 embedded in the insulating layer 112 on the first surface 110a, and the second wiring pattern 122 disposed on the insulating layer 112 on the second surface 110b. The first wiring pattern 121 and the second wiring pattern 122 may each be configured to enable signal transmission. The first wiring pattern 121 and the second wiring pattern 122 may be connected to each other through a via 124 embedded in the insulating layer 112.

The reinforcement patterns 131 and 132 may include the first reinforcement pattern 131 embedded in the insulating layer 112 on the first surface 110a. The first reinforcement pattern 131 may be disposed around the cavity 119 to be spaced apart from the edge of the cavity 119, and may be configured to be separated from the first wiring pattern 121. That is, the first reinforcement pattern 131 may be configured as a physically or electrically isolated pattern so as not to be used for signal transmission, or may be connected to a ground pattern. The first reinforcement pattern 131 may include metal, and specifically may include copper (Cu).

Based on the direction parallel to the first surface 110a, the first reinforcement pattern 131 is covered with the insulating layer 112 so as not to be exposed into the cavity 119. In the height measured in the direction perpendicular to the first surface 110a, the first reinforcement pattern 131 may have the same height as the first wiring pattern 121. Here, ‘the same height’ refers to a level of height that can be considered equivalent within the relevant technical field, including situations where the height may vary due to limitations and/or errors in the manufacturing process or measurement methods. The first wiring pattern 121 may be disposed to be spaced apart from the first reinforcement pattern 131 in a direction away from the cavity 119.

The reinforcement patterns 131 and 132 may include the second reinforcement pattern 132 disposed on the insulating layer 112 on the second surface 110b. The second reinforcement pattern 132 may be disposed around the cavity 119 to be spaced apart from the edge of the cavity 119, and may be configured to be separated from the second wiring pattern 122. That is, the second reinforcement pattern 132 may be configured as a physically or electrically isolated pattern so as not to be used for signal transmission. The second reinforcement pattern 132 may include metal, and specifically may include copper (Cu).

The second reinforcement pattern 132 may protrude above the second surface 110b to have the same height as the second wiring pattern 122. Here, ‘the same height’ refers to a level of height that can be considered equivalent within the relevant technical field, including situations where the height may vary due to limitations and/or errors in the manufacturing process or measurement methods. The second wiring pattern 122 may be disposed to be spaced apart from the second reinforcement pattern 132 in a direction away from the cavity 119. The second reinforcement pattern 132 may be disposed so that at least a part of the second reinforcement pattern 132 overlaps the first reinforcement pattern 131 along a direction perpendicular to the first surface 110a.

By providing the reinforcement patterns 131 and 132 of metal around the cavity 119 on the substrate 110 that includes an insulating resin, as mentioned above, it is possible to suppress the occurrence of cracks in the resin area on the edge of the cavity 119 during the panel level package (PLP) process.

The electronic device package 100 may be a fan-out semiconductor package, and the connection end of the electronic device 70 may be disposed to be positioned in the cavity 119 of the circuit board 101 on the first surface 110a of the substrate 110. One surface of a redistribution layer 150 may be disposed on the first surface 110a of the substrate 110 so that the electronic device 70 may be connected, and the first wiring pattern 121 of the circuit board 101 may be also connected to the redistribution layer 150. A connection pad 151 is disposed on the other surface of the redistribution layer 150, and a connection terminal 154 may be connected to the connection pad 151.

At least a part of the electronic device 70 and the second surface 110b of the substrate 110 may be covered with a sealing member 92. The sealing member 92 may cover the second reinforcement pattern 132 disposed on the second surface 110b and at least a part of the second wiring pattern 122. The second wiring pattern 122 disposed on the second surface 110b may be partially exposed from the sealing member 92 and function as a connection pad.

An insulating protective layer 141 may be disposed between the first surface 110a of the substrate 110 and the redistribution layer 150. The insulating protective layer 141 may be an underfill resin that may fill gaps to protect a connection portion between the electronic device 70 and the redistribution layer 150. The insulating protective layer 141 may include a photo-imageable dielectric (PID) resin disposed between the substrate 110 and the redistribution layer 150. The first surface 110a of the circuit board 101 is provided with a first reinforcement pattern 131 of metal around the edge of the cavity 119, thereby reducing application defects when applying the photo-imageable dielectric resin in the PLP process.

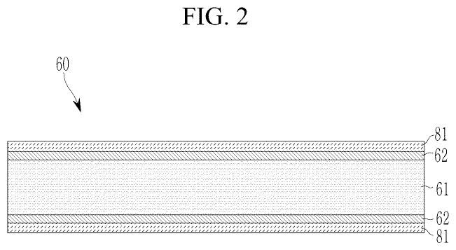

FIGS. 2 to 14 are cross-sectional process views illustrating a method of fabricating a circuit board according to an embodiment.

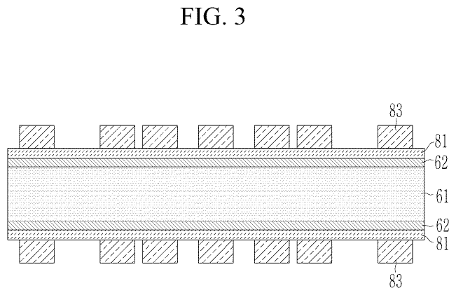

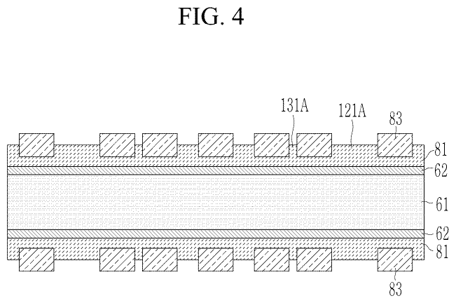

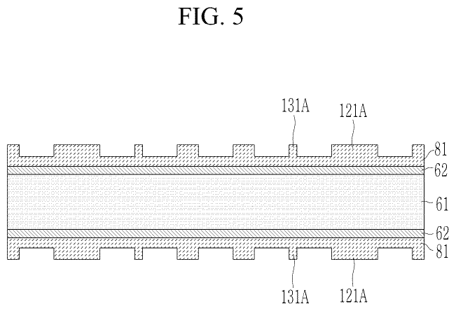

Referring to FIGS. 2 to 5, a carrier substrate 60 on which a first seed layer 81 is disposed on at least one surface is prepared, and a first wiring pattern layer 121A and a first reinforcement pattern layer 131A is formed on the first seed layer 81 through a circuit formation process. The carrier substrate 60 may be a substrate in which copper foil layers 62 are stacked on both sides of an insulating material 61, and the first seed layer 81 and the copper foil layer 62 may be separated from each other (see FIG. 2). A plating resist pattern 83 removed through exposing and developing may be formed only in the portion where the first wiring pattern layer 121A and the first reinforcement pattern layer 131A are to be formed on the carrier substrate 60 (see FIG. 3). The first wiring pattern layer 121A and the first reinforcement pattern layer 131A may be formed by plating a conductive metal on the portion of the first seed layer 81 exposed through the opening of the patterned plating resist pattern 83 (see FIG. 4). After forming the first wiring pattern layer 121A and the first reinforcement pattern layer 131A, the plating resist pattern is removed (see FIG. 5).

The first seed layer 81 can be applied without limitation as long as it is used as a conductive metal for circuits in the circuit board field, and copper (Cu) is generally used. The first wiring pattern layer 121A and the first reinforcement pattern layer 131A may be connected to the first seed layer 81 of the carrier substrate 60, and may include the same type of metal as the first seed layer 81. For example, the first seed layer 81, the first wiring pattern layer 121A, and the first reinforcement pattern layer 131A may include copper (Cu).

In the present embodiment, it is shown that the first wiring pattern layer 121A and the first reinforcement pattern layer 131A are formed on both sides of the carrier substrate 60, but it is also possible to form the first wiring pattern layer 121A and the first reinforcement pattern layer 131A only on one surface of the carrier substrate 60, and this also falls within the scope of the present disclosure.

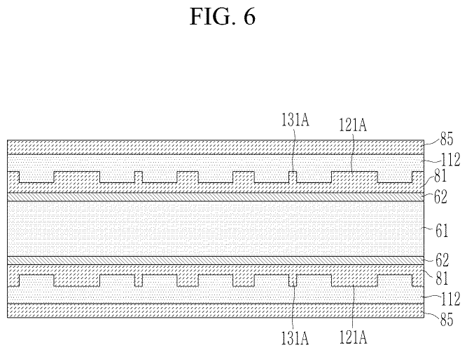

Referring to FIG. 6, the insulating layer 112 is stacked so that the first wiring pattern layer 121A and the first reinforcement pattern layer 131A are embedded, and the second seed layer 85 is formed on the upper surface of the insulating layer 112. The second seed layer 85 may be formed to form a second wiring pattern layer 122A and a second reinforcement pattern layer 132A. Any conductive metal may be used without limitation, but copper is generally used.

The insulating layer 112 may include a resin insulating layer. The insulating layer 112 may be made of a thermosetting resin such as an epoxy resin, a thermoplastic resin such as polyimide, or a resin impregnated with a reinforcing material such as glass fiber or an inorganic filler, for example, prepreg. The insulating layer 112 may also include, but is not limited to, thermosetting resin and/or photo-curing resin.

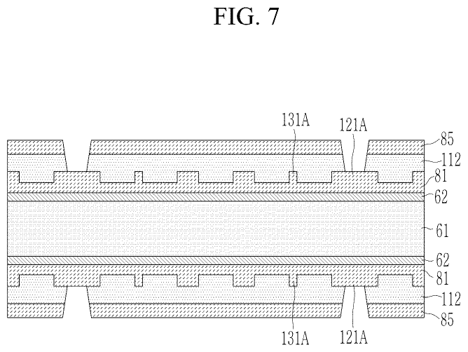

Referring to FIGS. 7 to 10, the second wiring pattern layer 122A and the second reinforcement pattern layer 132A may be formed on the insulating layer 112 through a circuit formation process. The second wiring pattern layer 122A and the second reinforcement pattern layer 132A may be formed in a similar method to the method of forming the first wiring pattern layer 121A and the first reinforcement pattern layer 131A. At this time, in order to form the via 124 connecting the first wiring pattern layer 121A and the second wiring pattern layer 122A, the insulating layer 112 may be partially etched to expose a part of the first wiring pattern layer 121A (see FIG. 7), and a plating process may be performed on the exposed portion of the first wiring pattern layer 121A.

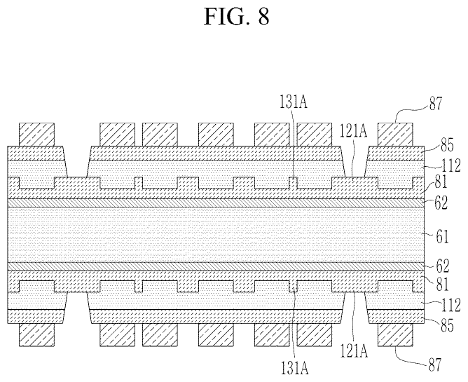

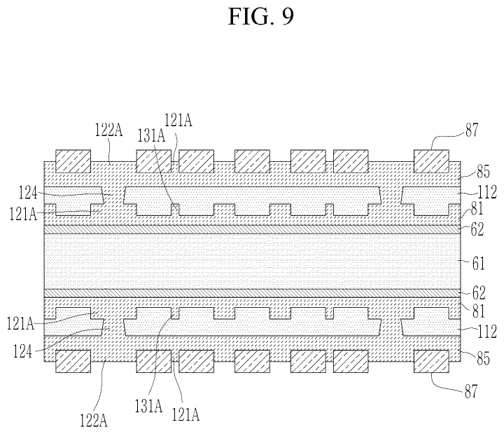

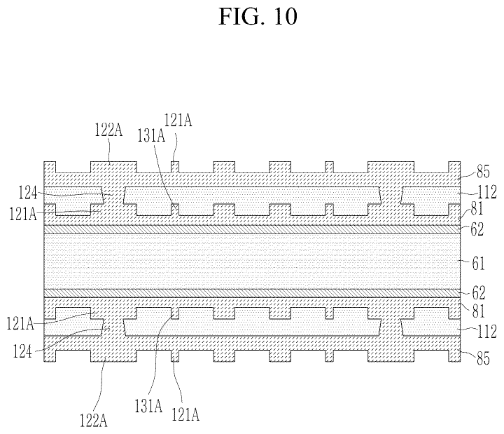

A plating resist pattern 87 removed through exposing and developing may be formed only in the portion where the second wiring pattern layer 122A and the second reinforcement pattern layer 132A are to be formed on the second seed layer 85 (see FIG. 8). The second wiring pattern layer 122A and the second reinforcement pattern layer 132A may be formed by plating a conductive metal on the portion of the second seed layer 85 exposed through the opening of the patterned plating resist pattern 87 (see FIG. 9). After forming the second wiring pattern layer 122A and the second reinforcement pattern layer 132A, the plating resist pattern 87 is removed (see FIG. 10). This completes embedded pattern substrate portions on both sides of the carrier substrate 60.

According to the illustrated embodiment, each of the embedded pattern substrate portion is shown to include one insulating layer 112 and the first wiring pattern layer 121A and the second wiring pattern layer 122A, which are metal layers disposed on both sides of the insulating layer 112. However, it is not limited thereto, and each of the embedded pattern substrate portion may include a greater number of build-up insulating layers and a greater number of build-up wiring pattern layers, which are also within the scope of the present disclosure.

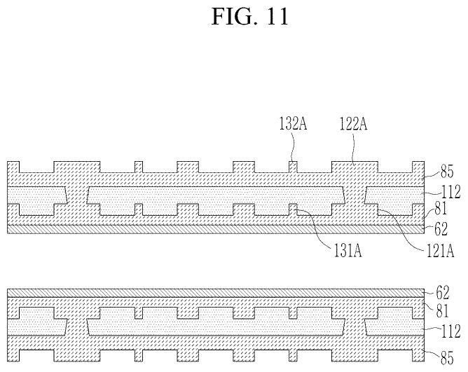

Referring to FIG. 11, the first seed layer 81 and the carrier substrate 60 are separated to prepare an embedded pattern substrate having a structure of ETS (Embedded Trace Substrate). A pair of embedded pattern substrates may be obtained by separating the first seed layer 81 formed on both sides of the carrier substrate 60 from the copper foil layer 62, and a separate process may be applied for each of the pair of embedded pattern substrates.

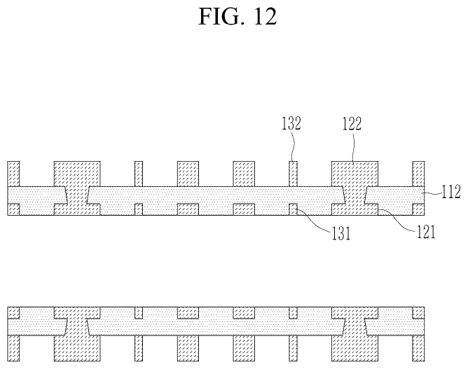

Referring to FIG. 12, the embedded pattern substrate obtained in FIG. 11 is soft-etched to remove the first seed layer 81 and the second seed layer 85. After removing the first seed layer 81 and the second seed layer 85, the first wiring pattern layer 121A and the first reinforcement pattern layer 131A embedded in the insulation layer 112 each forms the first wiring pattern 121 and the first reinforcement pattern 131, respectively. The second wiring pattern layer 122A and the second reinforcement pattern layer 132A disposed on one surface of the insulation layer 112 each forms the second wiring pattern 122 and the second reinforcement pattern 132, respectively.

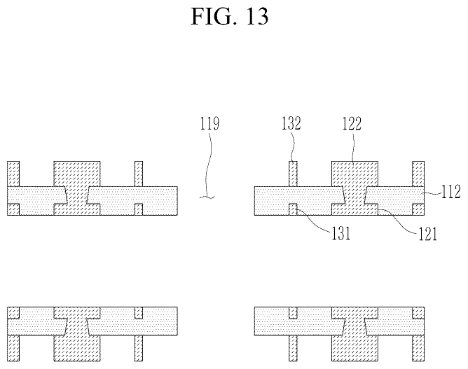

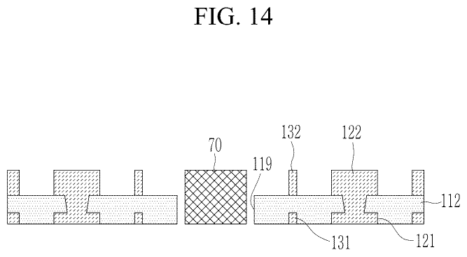

Referring to FIGS. 13 and 14, the center of the embedded pattern substrate obtained in FIG. 12 is etched to form the cavity 119. Cavity process may be performed by selecting from a variety of known processes, such as laser drilling, mechanical drilling, router processing and etching. The electronic device 70 may be accommodated in the cavity 119 (see FIG. 14).

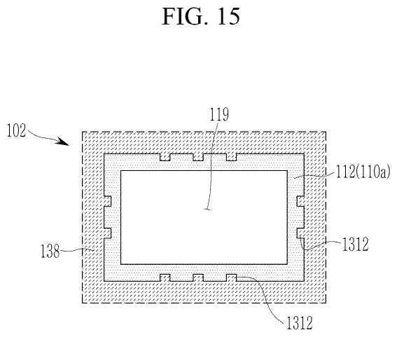

FIG. 15 is a bottom view of a circuit board according to an embodiment. FIG. 15 shows the first surface of the circuit board on which the embedded pattern is formed.

Referring to FIG. 15, the circuit board 102 according to the present embodiment includes a first reinforcement pattern 1312 embedded in the insulating layer 112 on the first surface 110a of the substrate 110. The first reinforcement pattern 1312 may include a plurality of reinforcement pads disposed to be spaced apart from each other along the edge of the cavity 119.

A ground pattern 138 may be disposed on the first surface 110a of the substrate 110, and the ground pattern 138 may have a shape surrounding the cavity 119. At this time, the plurality of reinforcement pads of the first reinforcement pattern 1312 may be connected to the ground pattern 138. That is, the first reinforcement pattern 1312 may have a shape that protrudes from the edge of the ground pattern 138 surrounding the cavity 119 toward the cavity 119 in a direction parallel to the first surface 110a.

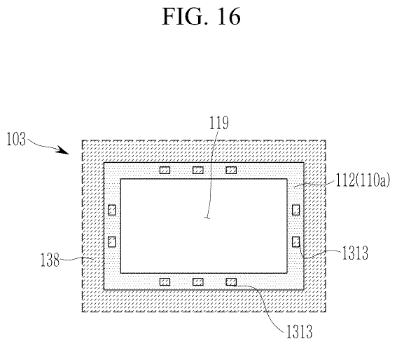

FIGS. 16 to 18 are plan views of circuit boards according to other embodiments.

Referring to FIG. 16, a first reinforcement pattern 1313 embedded in the first surface 110a of the substrate 110 according to the present embodiment may include a plurality of reinforcement pads spaced apart from each other along the edge of the cavity 119. At this time, a plurality of reinforcement pads of the first reinforcement pattern 131 may each have an isolated shape, spaced apart from the ground pattern 138 surrounding the cavity 119.

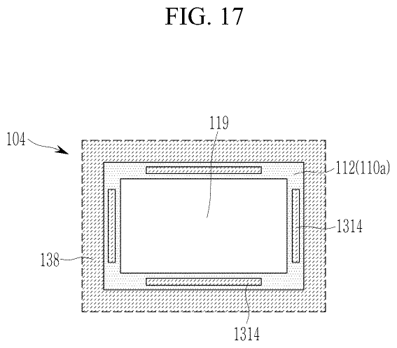

Referring to FIG. 17, a first reinforcement pattern 1314 embedded in the first surface 110a of the substrate 110 according to the present embodiment may include reinforcement pads disposed on each of the four sides along the edge of the cavity 119 including four sides. At this time, the plurality of reinforcement pads of the first reinforcement pattern 1314 may each have an isolated shape, spaced apart from the ground pattern 138 surrounding the cavity 119.

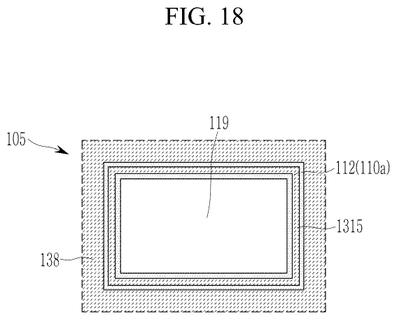

Referring to FIG. 18, a first reinforcement pattern 1315 embedded in the first surface 110a of the substrate 110 according to the present embodiment may be configured to continuously connected along the edge of the cavity 119 and surround the cavity 119. At this time, the first reinforcement pattern 1315 may have an isolated shape, spaced apart from the ground pattern 138 surrounding the cavity 119.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A circuit board, comprising:
a substrate having a first surface and a second surface facing each other, including an insulating layer disposed between the first surface and the second surface, and having a cavity penetrating in a direction perpendicular to the first surface;
a first wiring pattern embedded in the insulating layer on the first surface to enable signal transmission; and
a first reinforcement pattern embedded in the insulating layer on the first surface, disposed around the cavity to be spaced apart from an edge of the cavity, and separated from the first wiring pattern.

2. The circuit board of claim 1, wherein:
the first reinforcement pattern includes metal.

3. The circuit board of claim 1, wherein:
the first reinforcement pattern is electrically isolated.

4. The circuit board of claim 1, wherein:
the first reinforcement pattern is covered with the insulating layer so as to be not exposed to the cavity.

5. The circuit board of claim 1, wherein:
the first reinforcement pattern has the same height as the first wiring pattern.

6. The circuit board of claim 1, wherein:
the first wiring pattern is spaced apart from the first reinforcement pattern in a direction away from the cavity.

7. The circuit board of claim 1, further comprising:
a second wiring pattern disposed on the insulating layer on the second surface to enable signal transmission;
a second reinforcement pattern disposed on the insulating layer on the second surface around the cavity, spaced apart from the edge of the cavity, and separated from the second wiring pattern; and
a via embedded in the insulating layer and connecting the first wiring pattern and the second wiring pattern to each other.

8. The circuit board of claim 7, wherein:
the second reinforcement pattern protrudes above the second surface to have the same height as the second wiring pattern.

9. The circuit board of claim 7, wherein:
the second wiring pattern is spaced apart from the second reinforcement pattern in a direction away from the cavity.

10. The circuit board of claim 7, wherein:
the first reinforcement pattern and the second reinforcement pattern are disposed so that at least a part of the first reinforcement pattern and the second reinforcement pattern overlap each other along a direction perpendicular to the first surface.

11. The circuit board of claim 1, wherein:
the first reinforcement pattern includes a plurality of reinforcement pads spaced apart from each other along the edge of the cavity.

12. The circuit board of claim 1, wherein:
the first reinforcement pattern is configured to continuously connect along the edge of the cavity and surround the cavity.

13. The circuit board of claim 1, wherein:
the cavity includes four sides,
and the first reinforcement pattern includes reinforcement pads disposed on each of the four sides.

14. The circuit board of claim 7, wherein:
the first reinforcement pattern extends from the first surface and into the insulating layer.

15. The circuit board of claim 14, wherein:
a central axis of the first reinforcement pattern along a thickness direction of the circuit board is offset from a central axis of the second reinforcement pattern along the thickness direction of the circuit board.

16. An electronic device package, comprising:
a substrate having a first surface and a second surface facing each other, including an insulating layer disposed between the first surface and the second surface, and having a cavity penetrating in a direction perpendicular to the first surface;
a first wiring pattern embedded in the insulating layer on the first surface to enable signal transmission;
a first reinforcement pattern embedded in the insulating layer on the first surface, disposed around the cavity to be spaced apart from an edge of the cavity, and separated from the first wiring pattern;
a redistribution layer disposed on the first surface of the substrate; and
an electronic device accommodated in the cavity and connected to the redistribution layer.

17. The electronic device package of claim 16, further comprising:
an insulating protective layer disposed between the first surface of the substrate and the redistribution layer to cover the first reinforcement pattern.

18. The electronic device package of claim 16, wherein:
the first reinforcement pattern is electrically isolated.

19. The electronic device package of claim 16, wherein:
the first reinforcement pattern is covered with the insulating layer so as to be not exposed to the cavity.

20. The electronic device package of claim 16, wherein:
the first wiring pattern is spaced apart from the first reinforcement pattern in a direction away from the cavity.
